(19) United States
(12) Patent Application Publication
(10) Pub. No.: US 2013/0247976 A1
(43) Pub. Date: Sep. 26, 2013

(54) SOLAR CELL

(71) Applicants: Awankana Li, Tainan City (TW); Chia-Mei Lin, Tainan City (TW); Chih-Yu Jen, Kaohsiung City (TW); Ting Fang, Fangyuan Township (TW)

(72) Inventors: Awankana Li, Tainan City (TW); Chia-Mei Lin, Tainan City (TW); Chih-Yu Jen, Kaohsiung City (TW); Ting Fang, Fangyuan Township (TW)

(73) Assignee: MOTECH INDUSTRIES INC., New Taipei City (TW)

(21) Appl. No.: 13/848,882

(22) Filed: Mar. 22, 2013

(30) Foreign Application Priority Data
Mar. 22, 2012 (TW) 101109895

(51) Int. Cl. H01L 31/0224

(52) U.S. Cl. CPC H01L 31/022441
USPC 136/256

(57) ABSTRACT

A solar cell includes: a substrate having a front surface and a back surface; a dielectric layer disposed on the back surface and having at least two through holes to expose the back surface; at least two first electrode layers formed on the dielectric layer and respectively filling in the through holes to contact the substrate; at least one second electrode layer entirely formed on the dielectric layer and disposed between the first electrode layers; at least one space disposed on the dielectric layer; and at least one third electrode layer filled in the space to interconnect the second electrode layer and one of the first electrode layers.

### CROSS-REFERENCE TO RELATED APPLICATION

This application claims priority of Taiwanese application no. 101109895, filed on Mar. 22, 2012, which is hereby incorporated by reference in its entirety.

### FIELD OF THE INVENTION

This invention relates to a solar cell, more particularly to a crystalline silicon solar cell having a local back surface field structure.

### BACKGROUND OF THE INVENTION

Referring to FIG. 1, a conventional solar cell includes a silicon substrate 11, an emitter layer 12, a dielectric layer 13, a plurality of local back surface field structures 14, and a back electrode 15.

The silicon substrate 11 and the emitter layer 12 are formed with a p-n junction therebetween. The dielectric layer 13 is formed on a rear surface 111 of the silicon substrate 11 and is formed with a plurality of spaced-apart circular through holes 131. The local back surface field structures 14 are formed under the rear surface 111 of the silicon substrate 11 corresponding in position to the through holes 131. The local back surface field structures 14 have a doping concentration larger than that of the silicon substrate 11. The back electrode 15 is formed by screen printing aluminum paste on the dielectric layer 13, followed by firing the aluminum paste at high temperature (about 700° C. to 800° C.). A portion of the aluminum paste flows into the through holes 131 and thus, the rear electrode 15 has a surface layer portion 151 that is laminated on the dielectric layer 13, and a plurality of contact portions 152 respectively extending into the through holes 131 to contact the silicon substrate 11. During firing process, the aluminum in the aluminum paste would be mixed with the silicon of the silicon substrate 11 so as to form the local back surface field structures 14 made of Al—Si alloy in the silicon substrate 11. The local back surface field structures 14 improve carrier collection efficiency and photoelectric conversion efficiency.

In practice, at the high firing temperature, silicon of the silicon substrate 11 has high diffusibility in aluminum of the aluminum paste. Since, in the conventional solar cell, the back electrode 15 is formed into a continuous large area, the same cannot provide confinement to silicon diffusibility. It is thus not favorable to the formation of the local back surface field structures 14 since silicon flows outwardly from the silicon substrate 11 into the back electrode 15 and the local back surface field structures 14 has less amount of silicon. If outflow of silicon becomes more severe, a cavity 10 might be formed between the rear surface 111 of the silicon substrate 11 and the back electrode 15 (see FIG. 2). The cavity 10 would adversely influence conduction performance of the back electrode 15 and the quality of the local back surface field structures 14. Referring to FIGS. 3 and 4, another conventional solar cell includes a silicon substrate 11, a dielectric layer 13, a plurality of local back surface field structures 14, and a back electrode 15 formed on the dielectric layer 13. The back electrode 15 has two linear busbars 153 and three conductive portions 154 separated by the linear busbars 153. The dielectric layer 13 is formed with a plurality of through holes 131 that are in the form of a slot and that are perpendicular to the linear busbars 153. Similarly, each of the conductive portions 154 of the back electrode 15 has a surface layer portion 155 and a plurality of contact portions 156 that respectively extend into the through holes 131 to contact the local back surface field structures 14. As such, diffusion of silicon from the silicon substrate 11 would occur, thereby resulting in formation of a plurality of cavities and drawbacks attributed thereto.

Referring to FIGS. 5 and 6, to overcome the drawbacks occurred of the conventional solar cell shown in FIGS. 3 and 4, the back electrode 15 is modified to be not formed into a continuous area. To be specific, the back electrode 15 includes a plurality of spaced-apart conductive sections 157 each of which has a first portion 158 formed on the dielectric layer 13 and a contact portion 159 that extends into a respective one of the through holes 131. In this configuration, since the back electrode 15 is divided into a plurality of spaced-apart conductive sections 157, diffusion of the silicon from the silicon substrate 11 is confined. Besides, each of the conductive sections 157 has a limited size so that saturation of silicon would be quickly achieved and diffusion of silicon would be limited. Accordingly, formation of the cavities would may be alleviated.

However, in the configuration shown in FIGS. 5 and 6, the back electrode 15 has a relatively small area, thereby resulting in inferior conductivity and high series resistance. Also, as shown in FIGS. 5 and 6, current in one of the conductive sections 157 should be transmitted to another one of the conductive sections 157 through the busbars 153. Accordingly, the current transmission and electrical conductivity are adversely affected.

### SUMMARY OF THE INVENTION

Therefore, an object of the present invention is to provide a solar cell that can overcome cavity problem and inferior conductivity associated with the prior art.

Accordingly, a solar cell of this invention includes:

a substrate having a front surface and a back surface opposite to the front surface;

an emitter layer formed in the substrate under the front surface;

a dielectric layer disposed on the back surface and having at least two through holes to expose the back surface;

at least two first electrode layers formed on the dielectric layer and respectively filling in the through holes to contact the substrate;

at least one second electrode layer entirely formed on the dielectric layer and disposed between the first electrode layers; and

at least one third electrode layer filled in a space which is substantially defined by the second electrode layer and one of the first electrode layers so that the at least one third electrode layer interconnects the second electrode layer and the one of the first electrode layers.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a sectional view of a conventional solar cell;

FIG. 2 is a scanning electron microscope (SEM) picture showing a cavity formed in the conventional solar cell;

FIG. 3 is a bottom view of another conventional solar cell;

FIG. 4 is a sectional view taken long line IV-IV in FIG. 3;

FIG. 5 is a bottom view of yet another conventional solar cell;

FIG. 6 is a sectional view taken along line VI-VI in FIG. 5;

FIG. 7 is a bottom view of a first preferred embodiment of a solar cell according to this invention;

FIG. 8 is a sectional view taken along line VIII-VIII in FIG. 7;

FIG. 9 is a bottom view showing a modification of the first preferred embodiment, which includes a plurality of first electrode layers, third electrode layers, through holes, spaces, and local back surface field structures;

FIG. 10 is a scanning electron microscope (SEM) picture of the first preferred embodiment;

FIG. 11 is a fragmentary bottom view of a second preferred embodiment of a solar cell according to this invention;

FIG. 12 is a fragmentary bottom view of a third preferred embodiment of a solar cell according to this invention;

FIG. 13 is a fragmentary bottom view of a fourth preferred embodiment of a solar cell according to this invention;

FIG. 14 is a fragmentary bottom view of a fifth preferred embodiment of a solar cell according to this invention;

FIG. 15 is a fragmentary bottom view of a sixth preferred embodiment of a solar cell according to this invention;

FIG. 16 is a fragmentary bottom view of a seventh preferred embodiment of a solar cell according to this invention;

FIG. 17 is a sectional view taken along line XVII-XVII in FIG. 16;

FIG. 18 is a fragmentary bottom view of an eighth preferred embodiment of a solar cell according to this invention;

FIG. 19 is a fragmentary bottom view of a ninth preferred embodiment of a solar cell according to this invention; and

FIG. 20 is a sectional view taken along line XX-XX in FIG. 19.

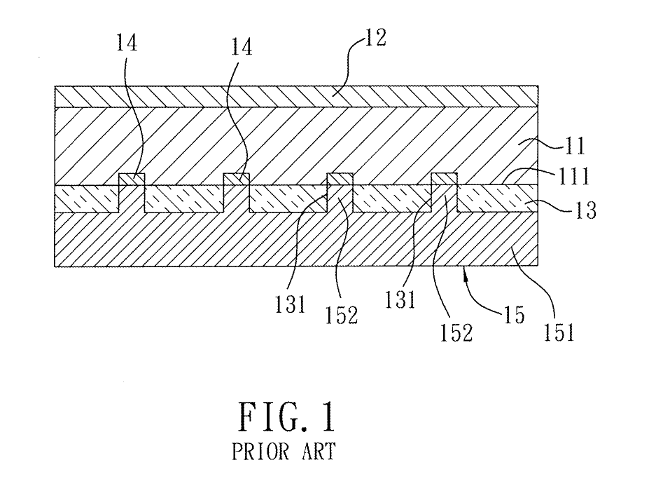

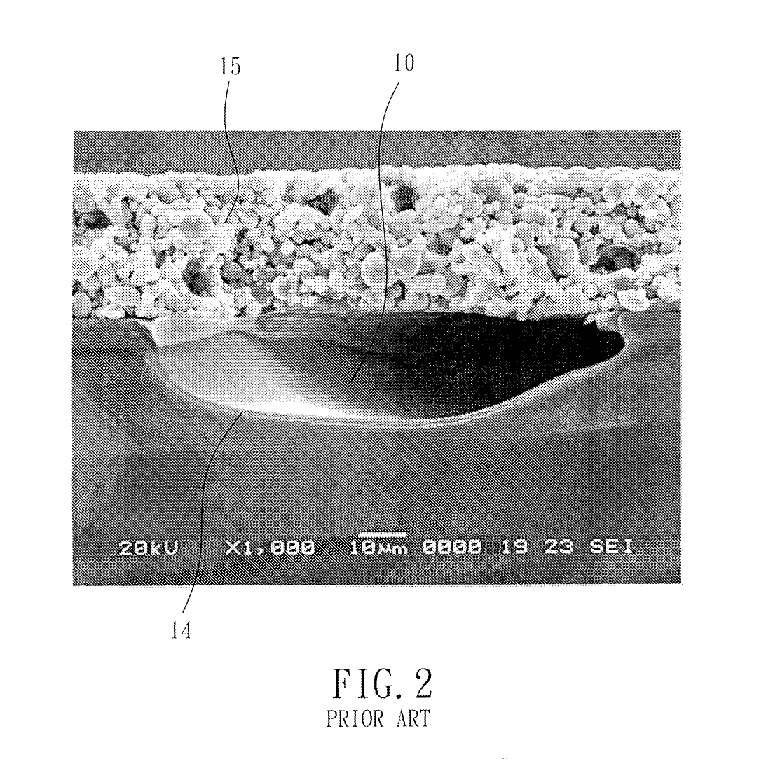

### DETAILED DESCRIPTION OF THE PREFERRED EMBODIMENTS

Before the present invention is described in greater detail, it should be noted herein that like elements are denoted by the same reference numerals throughout the disclosure.

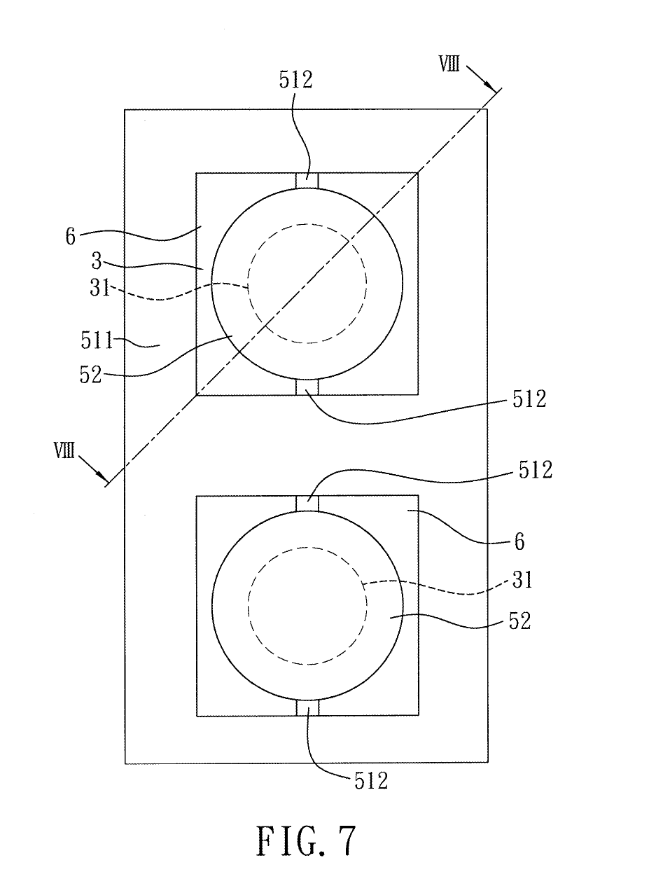

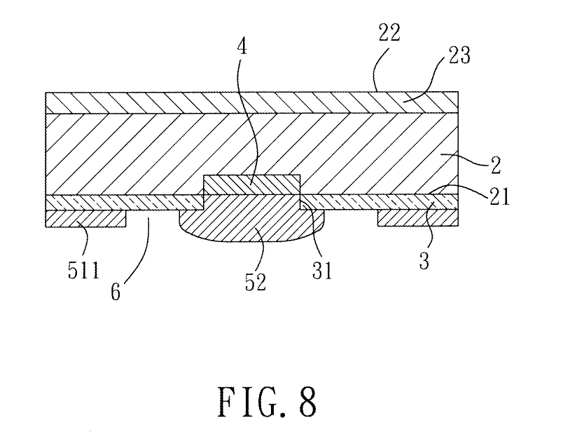

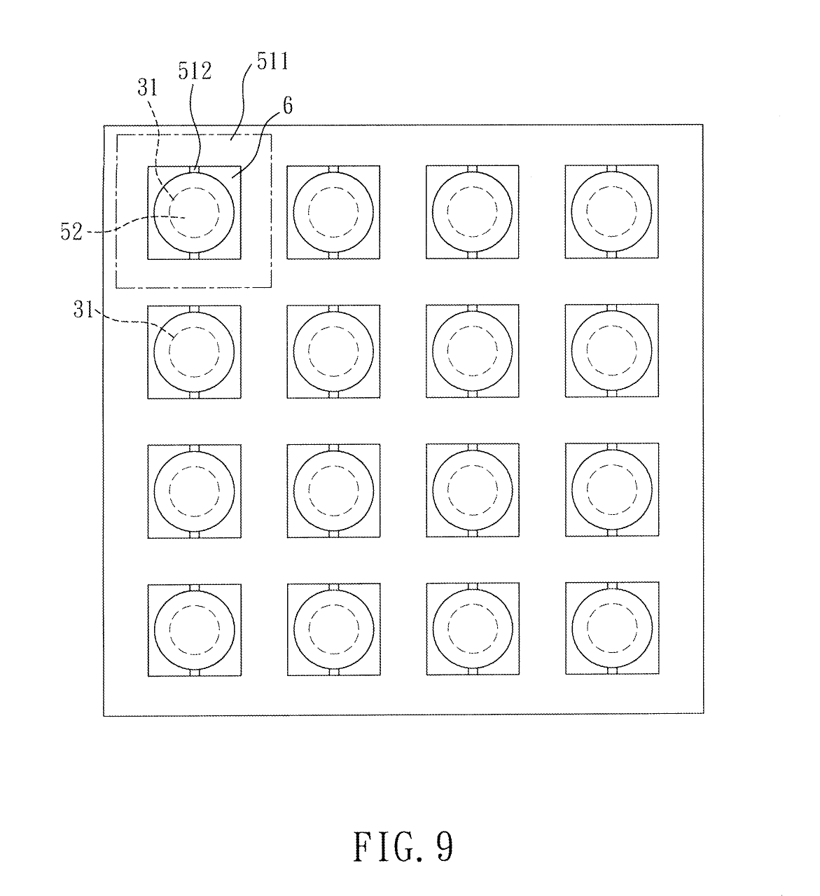

Referring to FIGS. 7 and 8, a solar cell of the first preferred embodiment according to this invention includes a substrate 2 made of silicon, an emitter layer 23, a dielectric layer 3, two first electrode layers 52, a second electrode layer 511, four third electrode layers 512, and two spaces 6 which are formed on the dielectric layer 3 and each of which is defined between the second electrode layer 511 and a respective one of the first electrode layers 52 to isolate the second electrode layer 511 and a respective one of the first electrode layers 52.

The substrate 2 has a front surface 22 and a back surface 21 opposite to the front surface 22. The front surface 22 is a light incident surface and can be roughened to improve light incidence efficiency. The emitter layer 23 is formed in the substrate 2 under the front surface 22. A p-n junction is formed between the emitter layer 23 and the substrate 2. In this embodiment, the substrate 2 is a p-type silicon substrate and the emitter layer 23 is made of a n-type semiconductor material. However, the conductivity types of the substrate 2 and the emitter layer 23 can be interchanged as long as the p-n junction is formed therebetween.

Besides, the emitter layer 23 may be formed with an anti-reflection layer (not shown) made of a material such as silicon nitride (SiNₓ) for reducing reflection of incident light and surface recombination velocity (SRV) of carriers, and raising light transmittance. In this embodiment, the solar cell is further formed with a front electrode (not shown) for outputting electric power. Since the front electrode and the anti-reflection layer are well known to a skilled artisan, detailed descriptions thereof are omitted herein for the sake of brevity.

The dielectric layer 3 is a passivation layer and is disposed on the back surface 21 of the substrate 2 for compensating surface defects of the substrate 2 so as to reduce carrier combination velocity on the back surface 21 and raise photoelectric conversion efficiency of the solar cell. The dielectric layer 3 is made of a material selected from the group consisting of oxides, nitrides, and the combinations thereof.

In this embodiment, the dielectric layer 3 is formed with at least two spaced-apart circular through holes 31 to expose the substrate 2. It should be noted that the shape of the through holes 31 can vary and is not limited by the disclosure in this embodiment.

The substrate 2 further includes two local back surface field structures 4 that are formed in the substrate 2 underneath the back surface 21 and respectively exposed from the through holes 31. In this embodiment, the back surface field structures 4 are made of p-type semiconductor material of aluminum-silicon alloy, and have a doping concentration higher than that of the substrate 2. By virtue of the electric field of the back surface field structures 4, electrons movement in the substrate 2 toward the back surface 21 can be prevented and electrons are collected in the emitter layer 23, thereby improving carrier collection and photoelectric conversion efficiencies of the solar cell.

The first electrode layers 52 are formed on the dielectric layer 3 and respectively extend into the through holes 31 to contact the back surface field structures 4. The second electrode layer 511 is entirely formed on the dielectric layer 3. The third electrode layers 512 are disposed in the spaces 6 to interconnect the first electrode layers 52 and the second electrode layer 511.

In this embodiment, each of the spaces 6 and a respective one of the first electrode layers 52 are disposed in concentric relation substantially. That is, each of the first electrode layers 52 is surrounded by a respective one of the spaces 6 and is isolated from the second electrode layer 511 by the respective one of the spaces 6. Two of the third electrode layers 512 are formed in each of the spaces 6 to interconnect the second electrode layer 511 and a respective one of the first electrode layers 52. The materials for the first electrode layers 52 and the second electrode layer 511 can be the same or different. The third electrode layers 512 are made of a material different from or the same with that of the first electrode layers 52. Examples of the material for the third electrode layers 512 include aluminum, silver, zinc oxide, and nickel. Preferably, when the third electrode layers 512 are made of a material different from that of the first electrode layers 52, the material for the third electrode layers 512 has lower diffusibility for silicon than that of the first electrode layers 52. In this embodiment, the first electrode layers 52 and the second electrode layer 511 are made of aluminum and are formed by screen-printing aluminum paste, and the third electrode layers 512 are made of silver by another screen-printing and are filled in a part of the spaces 6.

The surface area of the dielectric layer 3 which is occupied by the first, second and third electrode layers 52, 511, 512 is greater than the area of the spaces 6.

The back surface field structures 4 are formed by mixing aluminum in the aluminum paste and silicon of the substrate 2 during forming the first, second, and third electrode layers 52, 511, 512 by firing process.

In this embodiment, since each of the third electrode layers 512 has a small area, diffusion of the silicon from the substrate 2 to the second electrode layer 511 through the first electrode layers 52 and the third electrode layers 512 can be limited. Moreover, silicon concentration in the third electrode layers 512 is easily saturated and thus silicon diffusion would be limited. Accordingly, enough silicon would be confined near the back surface 21 and mixed with aluminum so as to form superior back surface field structures 4. Without forming the cavities in the solar cell, photoelectric conversion efficiency and electrical conductivity can be improved.

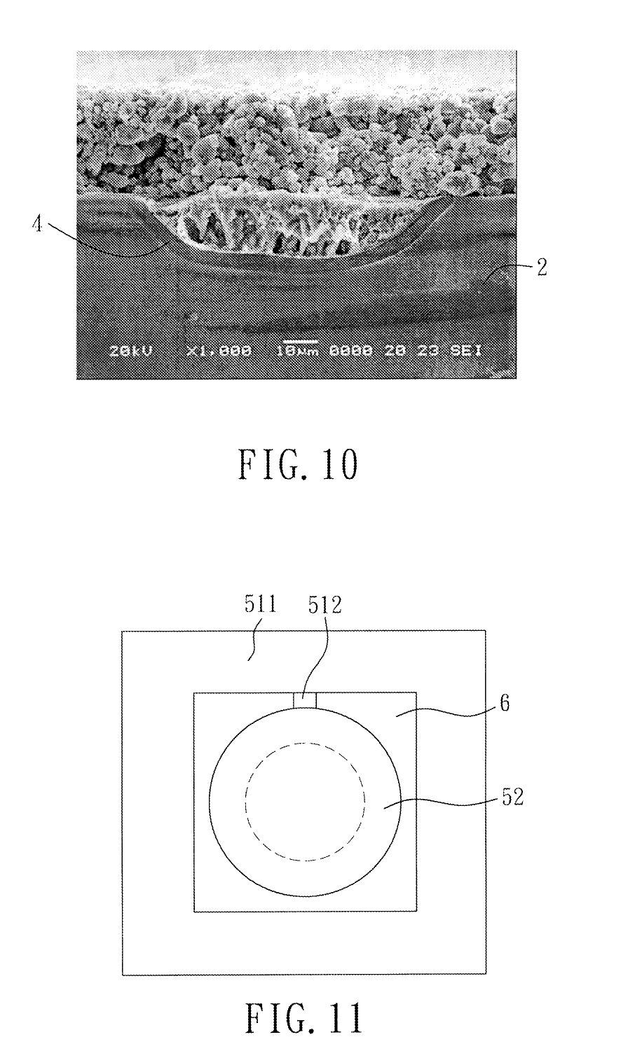

Referring to FIG. 10, the scanning electron microscope (SEM) image shows that no cavity is formed between the back surface 21 and the first electrode layers 52 and the back surface field structures 4 have sufficient thickness.

It should be noted that, the number of each of the elements, e.g., the first electrode layers 52, the third electrode layers 512, the through holes 31, the spaces 6, and the local back surface field structures 4, can vary based on actual requirements and should not be limited to the disclosure in this embodiment. For example, a solar cell of this invention can include a plurality of the first electrode layers 52, the third electrode layers 512, the through holes 31, the spaces 6, and the local back surface field structures 4 (see FIG. 7).

Referring to FIG. 11, the second preferred embodiment of the solar cell according to this invention is similar to that of the first preferred embodiment except that the solar cell contains one third electrode layer 512 formed in each of the spaces 6.

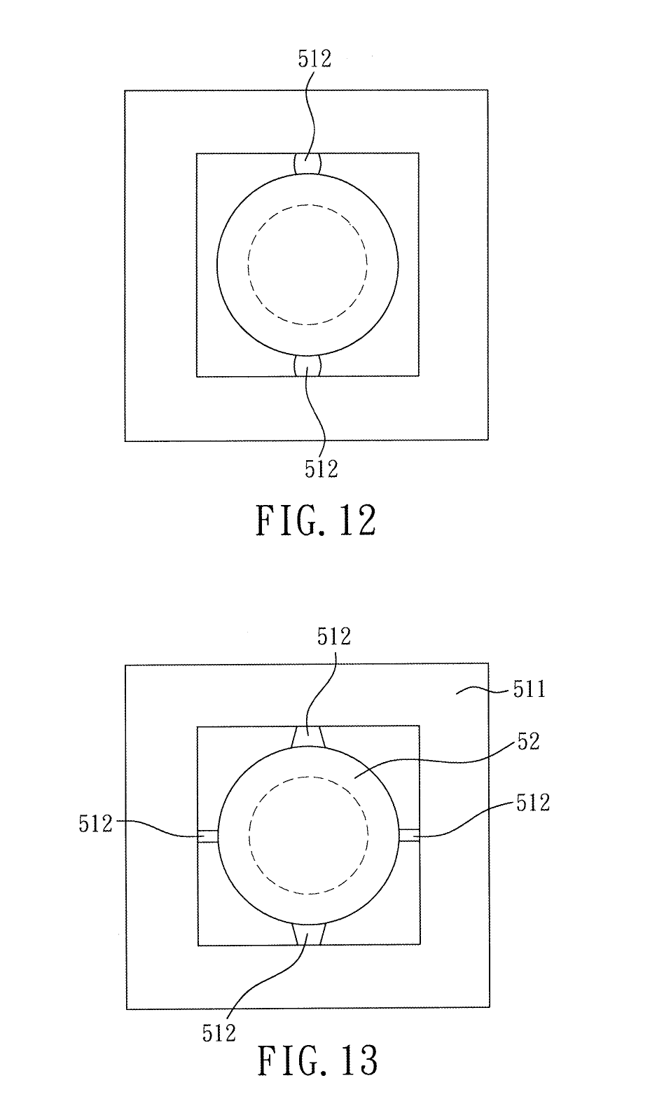

Referring to FIG. 12, the third preferred embodiment of the solar cell according to this invention is similar to that of the first preferred embodiment except that each of the third electrode layers 512 has curved lateral surfaces.

Referring to FIG. 13, the fourth preferred embodiment of the solar cell according to this invention is similar to that of the first preferred embodiment except that four spaced-apart third electrode layers 512 are formed in each of the spaces 6, two of which have a rectangular shape, and the other two of which have a trapezoidal shape.

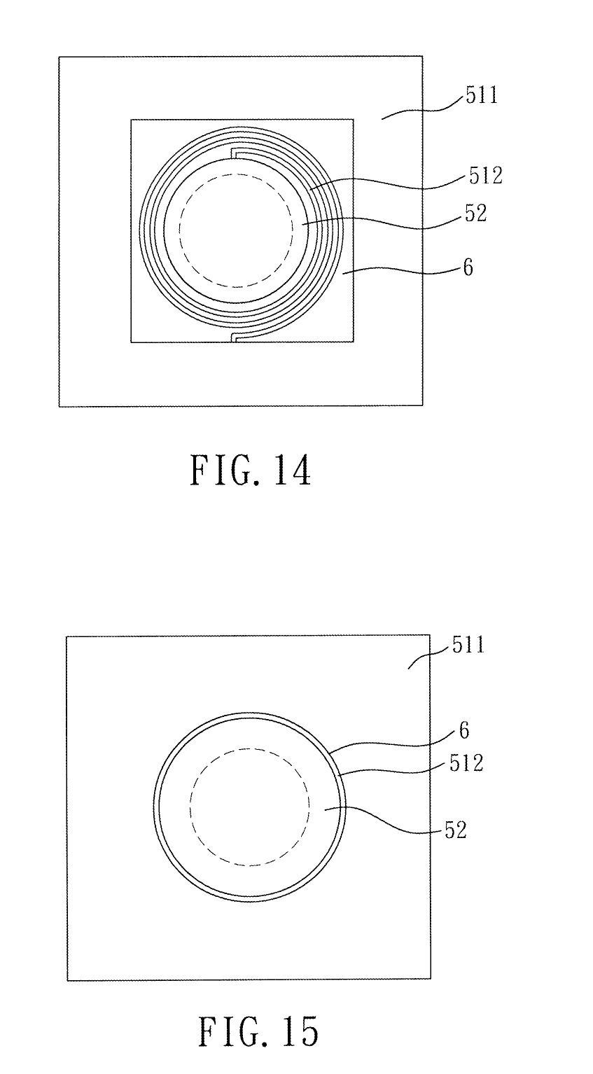

Referring to FIG. 14, the fifth preferred embodiment of the solar cell according to this invention is similar to that of the first preferred embodiment except that one third electrode layer 512 is formed in each of the spaces 6 and the third electrode layer 512 has a spiral shape and surrounds a respective one of the first electrode layers 52.

Referring to FIG. 15, the sixth preferred embodiment of the solar cell according to this invention is similar to that of the first preferred embodiment except that each of the spaces 6 is completely filled with the respective third electrode layer 512. It should be noted that, in such configuration, the third electrode layer 512 should be made of a material different from that of the first electrode layers 52, and the material for the third electrode layer 512 should have lower diffusibility for silicon than that of the first electrode layers 52. In this embodiment, the first and second electrode layers 52, 511 are made of aluminum. The third electrode layers 512 in the spaces 6 are made of silver that exhibits low silicon diffusibility. In this embodiment, since each of the first electrode layers 52, the second electrode layer 511, and a respective one of the third electrode layers 512 are connected, current transmission and photoelectric conversion efficiency can be improved.

In view of the above, when each of the spaces 6 is partly filled with the third electrode layer(s) 512 (as shown in the first to fifth preferred embodiments), the first electrode layers 52 can be made of a material the same with or different from that of the third electrode layer(s) 512. On the other hand, when each of the spaces 6 is completely filled with the third electrode layer 512 as shown in the sixth preferred embodiment, the material of the third electrode layers 512 is required to be different from that of the first electrode layers 52 and should have relatively low diffusibility for silicon so as to block diffusion of the silicon from the substrate 2 to the second electrode layer 511.

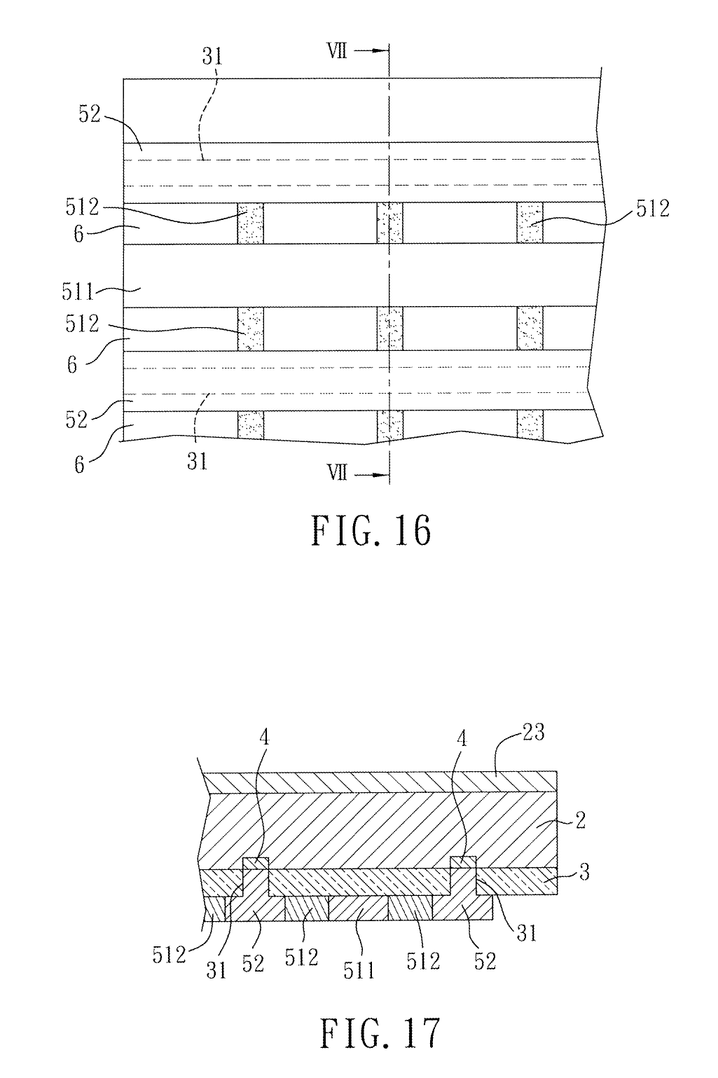

FIGS. 16 and 17 show the seventh preferred embodiment of the solar cell according to this invention, in which the second electrode layer 511, the first electrode layers 52, the through holes 31, and the spaces 6 respectively extend in a first direction, and the first electrode layers 52, the third electrode layers 512, the second electrode layer 511, and the spaces 6 are juxtaposed in a second direction perpendicular to the first direction. The second electrode layer 511 is disposed between the first electrode layers 52. A plurality of spaced-apart third electrode layers 512 are formed in each of the two spaces 6.

In this embodiment, the through holes 31 and the spaces 6 are in the form of a slot. The second electrode layer 511 and the first electrode layers 52 are made of aluminum. The third electrode layers 512 are made of silver.

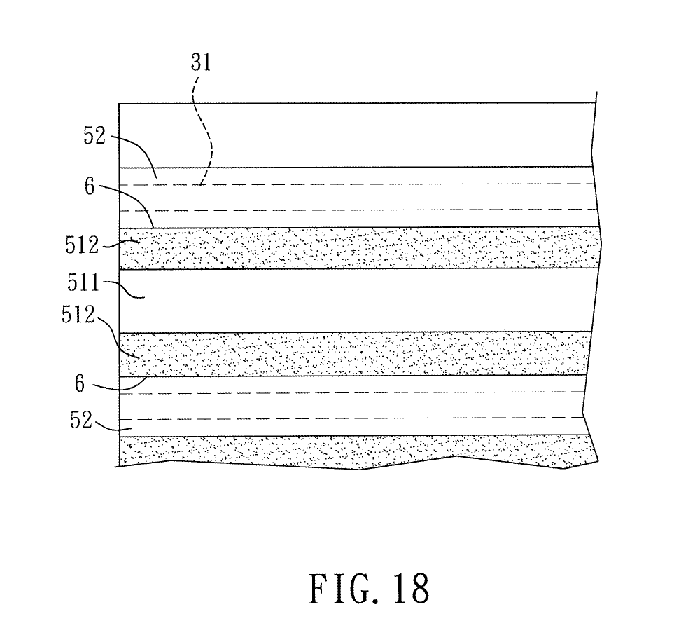

Referring to FIG. 18, the eighth preferred embodiment of the solar cell according to this invention is similar to that of the seventh preferred embodiment except that each of the spaces 6 is completely filled with a respective one of the third electrode layers 512.

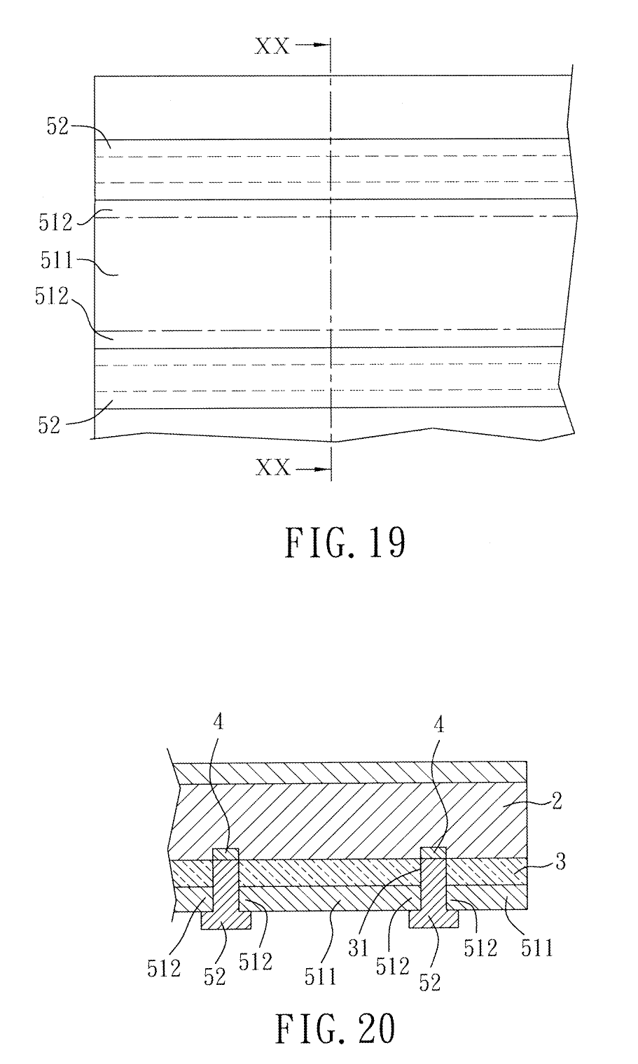

Referring to FIGS. 19 and 20, the ninth preferred embodiment of the solar cell according to this invention is similar to that of the eighth preferred embodiment except that the second electrode layer 511 and the third electrode layers 512 are made of the same material, i.e., silver. Each of broken lines in FIG. 19 is used to indicate a boundary between the second electrode layer 511 and a respective one of the third electrode layers 512. The first electrode layers 52 are made of aluminum. Each of the first electrode layers 52 has an end extending over a surface of a respective one of the third electrode layers 512 opposite to the dielectric layer 3.

It should be noted that, in each of the preferred embodiments of this invention, the number of each of the elements included in the solar cell can vary based on actual requirements. The rules of material selection for the first, second, and third electrode layers 52, 511, 512 in the seventh to ninth preferred embodiments are the same with those in the first to sixth preferred embodiments. Moreover, the solar cell in the seventh, eighth, or ninth embodiment may further include a busbar (not shown).

### Example

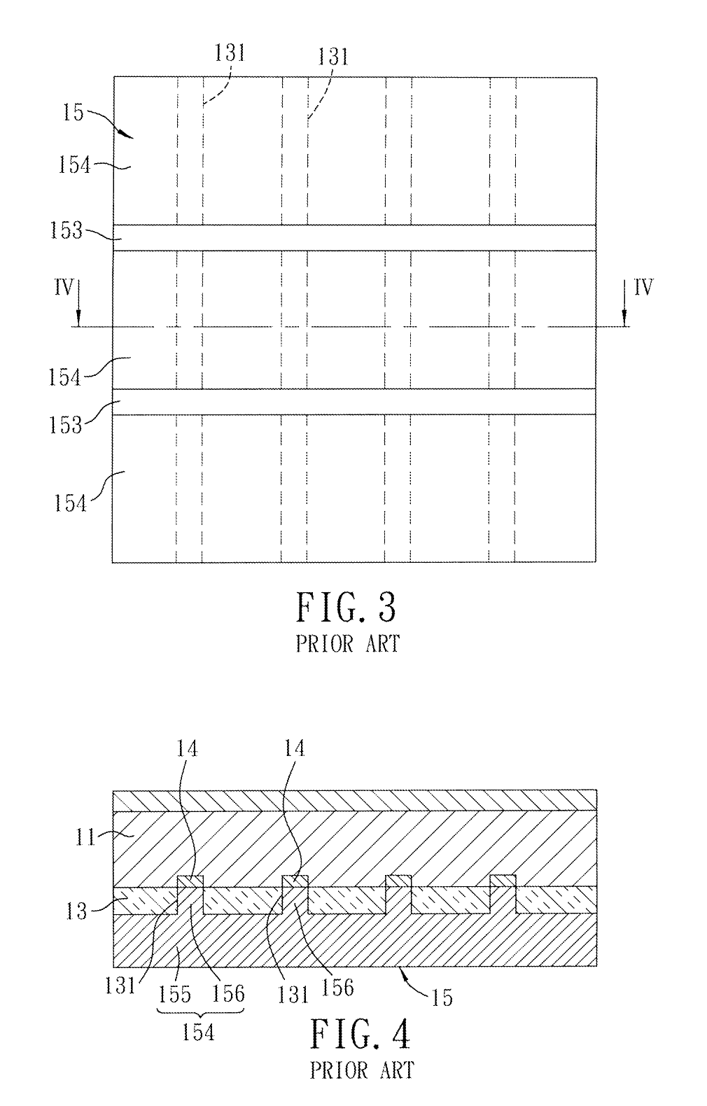

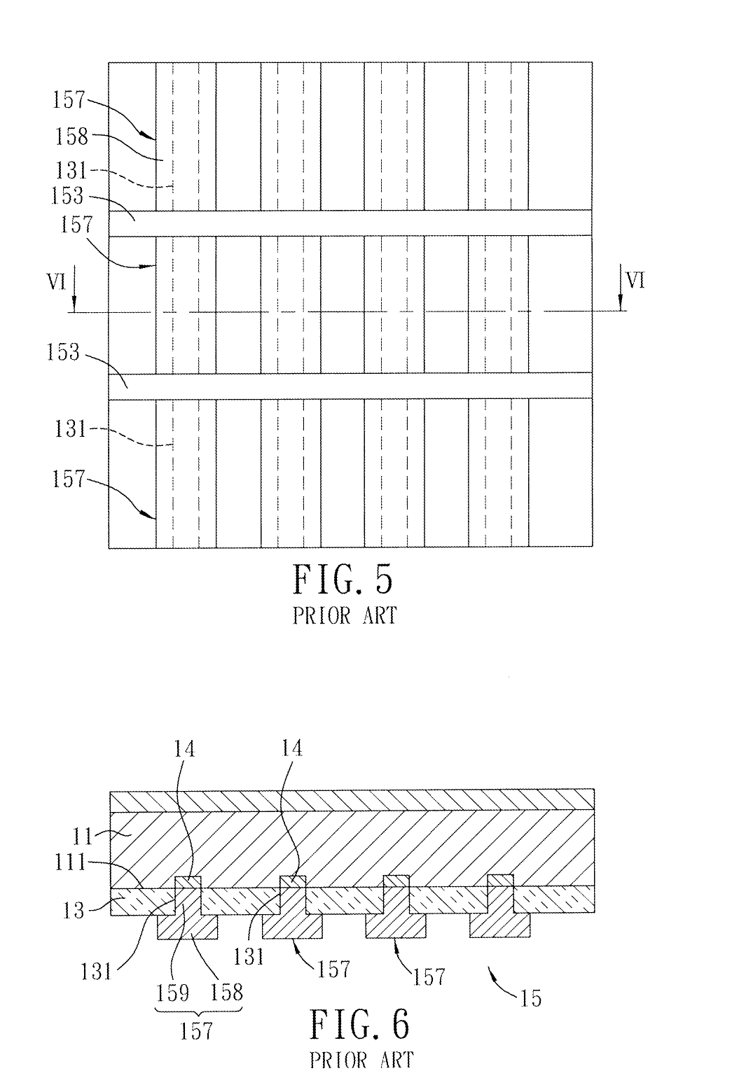

The conventional solar cells shown in FIGS. 3 and 5 were used as Comparative examples 1 and 2 to compare with the solar cell of the ninth preferred embodiment with respect to series resistance and cavity percentage.

TABLE 1

| | Series Resistance | Cavity Percentage |
|---|---|---|
| | (mΩ) | (%) |
| Comparative | 4.38 | 57.66 |
| Example 1 | | |
| Comparative | 6.66 | 12.38 |
| Example 2 | | |
| Ninth preferred | 4.63 | 28.97 |
| embodiment | | |

Referring to Table 1, the solar cell of the ninth preferred embodiment has a series resistance much smaller than that of Comparative Examples 2, and has a cavity percentage much lower than that of Comparative Examples 1. In this embodiment, a trade-off between the series resistance and the cavity percentage is reached, thereby simultaneously improving electrical conductivity and photoelectric conversion efficiency of the solar cell.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A solar cell, comprising:
a substrate having a front surface and a back surface opposite to said front surface;
an emitter layer formed in said substrate under said front surface;
a dielectric layer disposed on said back surface and having at least two through holes to expose said back surface;
at least two first electrode layers formed on said dielectric layer and respectively filling in said through holes to contact said substrate;
at least one second electrode layer entirely formed on said dielectric layer and disposed between said first electrode layers; and
at least one third electrode layer filled in a space which is substantially defined by said second electrode layer and one of said first electrode layers so that said at least one third electrode layer interconnects said second electrode layer and said one of said first electrode layers.

2. The solar cell of claim 1, wherein said space is partly filled with said third electrode layer.

3. The solar cell of claim 2, wherein said third electrode layer is made of a material the same with that of said first electrode layers.

4. The solar cell of claim 3, wherein the material of said first electrode layers is the same with that of said second electrode layer.

5. The solar cell of claim 3, wherein the material of said first electrode layers is different from that of said second electrode layer.

6. The solar cell of claim 2, wherein said third electrode layer is made of a material different from that of said first electrode layers.

7. The solar cell of claim 6, wherein the material of said third electrode layer has lower diffusibility for silicon than that of said first electrode layers.

8. The solar cell of claim 6, wherein the material of said first electrode layers is the same with that of said second electrode layer.

9. The solar cell of claim 6, wherein the material of said first electrode layers is different from that of said second electrode layer.

10. The solar cell of claim 6, wherein the material of said third electrode layer is the same with that of said second electrode layer.

11. The solar cell of claim 1, wherein said space is completely filled with said third electrode layer.

12. The solar cell of claim 11, wherein said third electrode layer is made of a material different from that of said first electrode layers.

13. The solar cell of claim 12, wherein the material of said third electrode layer has lower diffusibility for silicon than that of said first electrode layers.

14. The solar cell of claim 12, wherein the material of said first electrode layers is the same with that of said second electrode layer.

15. The solar cell of claim 12, wherein the material of said first electrode layers is different from that of said second electrode layer.

16. The solar cell of claim 12, wherein the material of said third electrode layer is the same with that of said second electrode layer.

17. The solar cell of claim 1, wherein said space and said one of said first electrode layers are disposed in concentric relation substantially.

18. The solar cell of claim 1, wherein said first electrode layers, said second electrode layer, and said through holes respectively extend in a first direction; one of said first electrode layers, said third electrode layer, and said second electrode layer being juxtaposed in a second direction perpendicular to said first direction.

19. The solar cell of claim 1, wherein said substrate further includes at least two local back surface field structures that are exposed from said through holes, and that are respectively connected to said first electrode layers.
